(19) United States
(12) Patent Application Publication
(10) Pub. No.: US 2009/0091004 A1
(43) Pub. Date: Apr. 9, 2009

(54) SEMICONDUCTOR DEVICE

(75) Inventor: Hirosada KOGANEI, Kawasaki (JP)

Correspondence Address: SUGHRUE MION, PLLC, 2100 PENNSYLVANIA AVENUE, N.W., SUITE 800, WASHINGTON, DC, 20037, US

(73) Assignee: NEC Electronics Corporation, Kawasaki (JP)

(21) Appl. No.: 12/247,528

(22) Filed: Oct. 8, 2008

(30) Foreign Application Priority Data
Oct. 9, 2007 (JP) 2007-263564

(51) Int. Cl. H01L 23/58

(52) U.S. Cl. 257/637; 257/E23.001

(57) ABSTRACT

A semiconductor device according to one aspect of the present invention includes a semiconductor substrate, an interlayer insulating film formed over the semiconductor substrate, a metal wiring formed over the interlayer insulating film, a protective insulating film formed on the metal wiring, and a resin film formed within a region having one side shorter than a predetermined length on the protective insulating film. The resin film covers all regions in which an interval of the metal wirings is equal to or less than a predetermined interval.

### BACKGROUND OF THE INVENTION

1. Field of the Invention

The present invention relates to a semiconductor device including a passivation film.

2. Description of Related Art

A nitride film has generally been employed as a passivation film for protecting a surface of a semiconductor element or the like. The nitride film is formed on wirings and semiconductor elements disposed over a substrate, which improves moisture resistance of the semiconductor device and prevents short-circuit of the wirings caused by attachment of foreign substances or the like to the surface of the semiconductor device. However, the nitride film formed on the wirings made of metal or the like has poor adhesion with the metal. Therefore, cracking and stripping of the nitride film easily occur in a process after separating the semiconductor device.

FIGS. 2A and 2B each shows a cross sectional view of a part of a semiconductor device having a nitride film formed on wirings or the like disposed over a substrate. As shown in FIG. 2A, an interlayer insulating film 92 is formed on a substrate 91 made of GaAs, for example. Then wirings 93a made of Au or the like are formed thereon, for example. A nitride film 94 is formed on the wirings 93a as a passivation film protecting the wirings 93a or the like. As described above, the nitride film 94 has poor adhesion with a metal, and especially with Au wirings. Further, end parts of the wirings 93a are susceptible to external stress. Therefore, as shown in FIG. 2B, cracking and stripping and so on occur in the nitride film 94. Further, when the wirings 93a are formed close to each other and each potential of the wirings 93a is different from each other, this potential difference may cause the metal to move between the wirings, which is so-called migration. The wirings 93a short out due to a metal 100 which is moved as a result of the migration.

In recent years, a technique of forming a resin film composed of polyimide or the like on a nitride film so as to suppress cracking and stripping of the nitride film has been employed. A semiconductor integrated circuit device having the resin film formed on the nitride film is disclosed in Japanese Unexamined Patent Application Publication No. 8-241968. Further, Japanese Unexamined Patent Application Publication No. 10-12605 discloses a semiconductor device having the resin film formed on the nitride film, for example. In the semiconductor integrated circuit device disclosed in Japanese Unexamined Patent Application Publication No. 8-241968, a passivation film composed of a silicon nitride film or the like is formed on a whole surface of a substrate where wirings are disposed. Then the resin film is formed above the passivation film. This resin film may be formed over each of a memory cell array, a peripheral circuit, and so on, respectively. In the semiconductor device disclosed in Japanese Unexamined Patent Application Publication No. 10-12605, a cover film composed of SiON is formed on an electrode pad disposed over the substrate. Then the polyimide film is formed thereon. Further, a function element having the resin film patterned over a substrate where a wiring layer is formed is disclosed in Japanese Unexamined Patent Application Publication No. 2000-82723, for example.

However, in the semiconductor integrated circuit device disclosed in Japanese Unexamined Patent Application Publication No. 8-241968, the resin film is formed over the memory cell array, the peripheral circuit, and so on which are disposed over the substrate. Further, in the semiconductor device disclosed in Japanese Unexamined Patent Application Publication No. 10-12605, the polyimide film is formed on the cover film disposed over the substrate. Further, in the function element disclosed in Japanese Unexamined Patent Application Publication No. 2000-82723, the resin is formed over the function element other than the peripheral part such as a bump disposed over the function element. In summary, in Japanese Unexamined Patent Application Publication Nos. 8-241968, 10-12605, and 2000-82723, the resin film is formed over a wide range of the semiconductor device having the wiring or the like disposed on the substrate. When the resin film is formed over the wide range of the substrate, the semiconductor device may be bent due to the stress produced when the resin film is compressed or stretched.

FIG. 3A shows a plan view of an example of the semiconductor device having the resin film formed on the nitride film. FIG. 3B shows a cross sectional view of the semiconductor device taken along the line III-III of FIG. 3A. As shown in FIGS. 3A and 3B, the interlayer insulating film 92 is formed on the substrate 91 composed of GaAs, and electrode pads 93b and wirings 93a connected to the electrode pads 93b are formed thereon. The nitride film 94 is formed on the wirings 93a and the electrode pads 93b as a passivation film to have a film thickness of about 1 μm or less, for example. The nitride film 94 formed on the electrode pads 93b is removed so as to form electrode pad openings 94a. Then a resin film 95 is formed on the nitride film 94. This resin film 95 is formed to cover the wirings 93a for about 1 μm or more in a height direction and about 1 μm or more in a horizontal direction. The resin film 95 near the electrode pads 93b is removed to form resin film openings 95a. A minimum width of the wiring 93a is approximately 4 μm, and minimum distance between wirings is approximately 4 μm. Further, each thickness of the wiring 93a and the electrode pad 93b is approximately 1 to 4 μm. As shown in FIGS. 3A and 3B, the resin film 95 is formed on the nitride film 94 so as to suppress the cracking and the stripping and the like of the nitride film 94. However, since the resin film 95 is formed over the wide range of the substrate 91, the semiconductor device may be bent due to the stress of the resin film, which causes a chip crack.

The chip crack will be described with reference to FIG. 4. FIG. 4 shows a cross sectional view of a semiconductor device having a resin film 102 formed substantially over a whole surface of a semiconductor device 101. As shown in FIG. 4, when the resin film 102 is formed substantially over the whole surface of the semiconductor device 101, the semiconductor device 101 is bent due to the stress when the resin film 102 is compressed or stretched, which causes a chip crack 103.

### SUMMARY

A semiconductor device according to one aspect of the present invention includes a semiconductor substrate, an interlayer insulating film formed over the semiconductor substrate, a metal wiring formed over the interlayer insulating film, a protective insulating film formed on the metal wiring, and a resin film formed within a region having one side shorter than a predetermined length on the protective insulating film. The resin film covers all regions in which an interval of the metal wirings is equal to or less than a predetermined interval.

According to the present invention, the resin film is formed within the region having one side shorter than the predetermined length and covers all the regions having interval of the metal wirings equal to or less than the predetermined interval. Accordingly, it is possible to reduce the stress when the resin film is compressed or stretched.

According to the semiconductor device of the present invention, it is possible to prevent the chip crack.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1A shows a plan view showing a semiconductor device according to a first embodiment;

FIG. 1B shows a cross sectional view of the semiconductor device taken along the line I-I of FIG. 1A;

FIG. 2A shows a cross sectional view of a conventional semiconductor device in which a nitride film is formed;

FIG. 2B shows a cross sectional view of the semiconductor device showing cracking and stripping of the nitride film;

FIG. 3A shows a cross sectional view of the semiconductor device having a resin film formed on the nitride film;

FIG. 3B shows a cross sectional view of the semiconductor device taken along the line III-III of FIG. 3A; and

FIG. 4 shows a cross sectional view of the semiconductor device having a resin film formed over a chip.

### DETAILED DESCRIPTION OF THE PREFERRED EMBODIMENTS

The invention will now be described herein with reference to illustrative embodiments. Those skilled in the art will recognize that many alternative embodiments can be accomplished using the teachings of the present invention and that the invention is not limited to the embodiments illustrated for explanatory purposes.

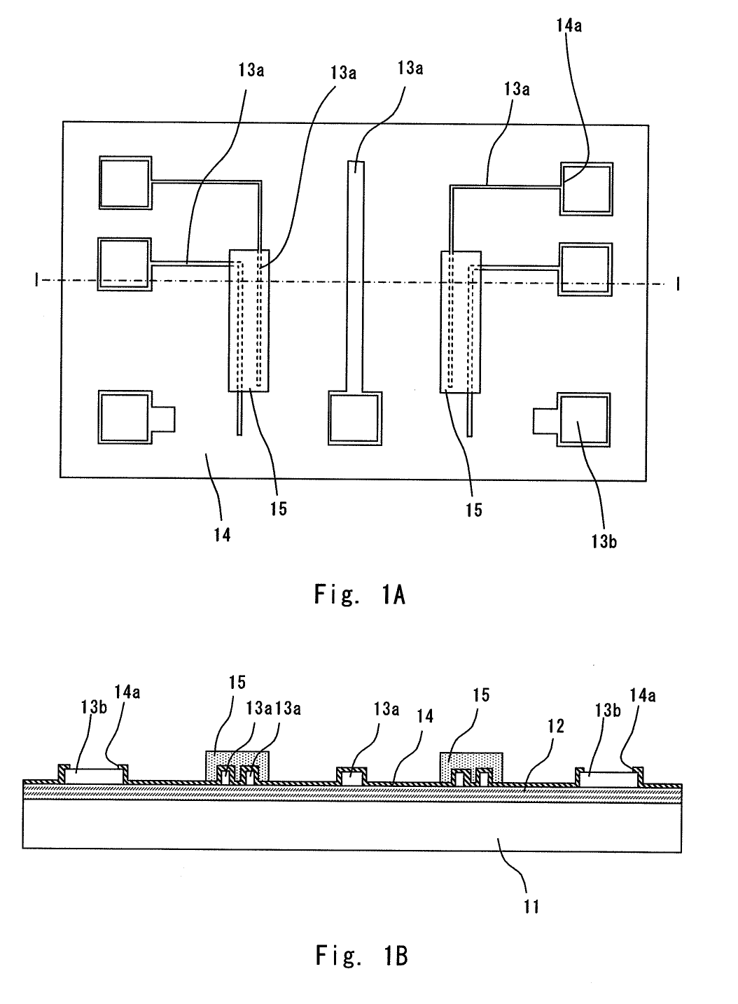

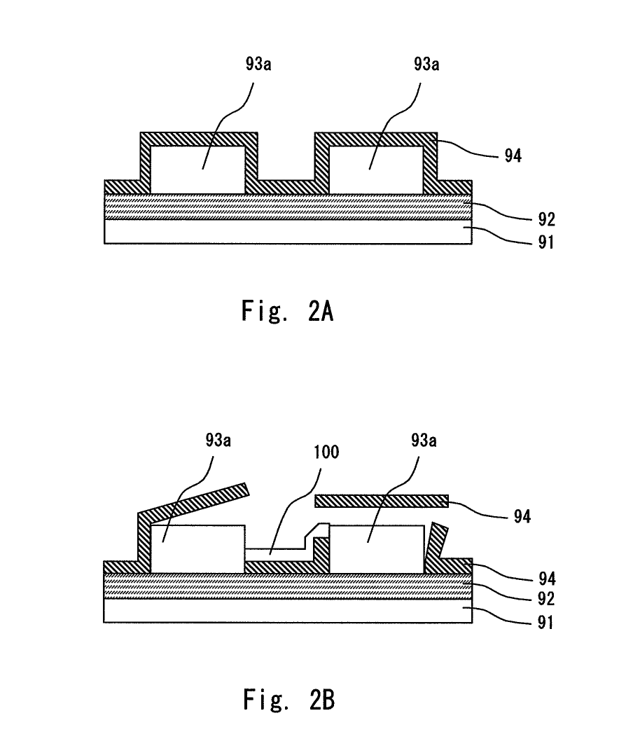

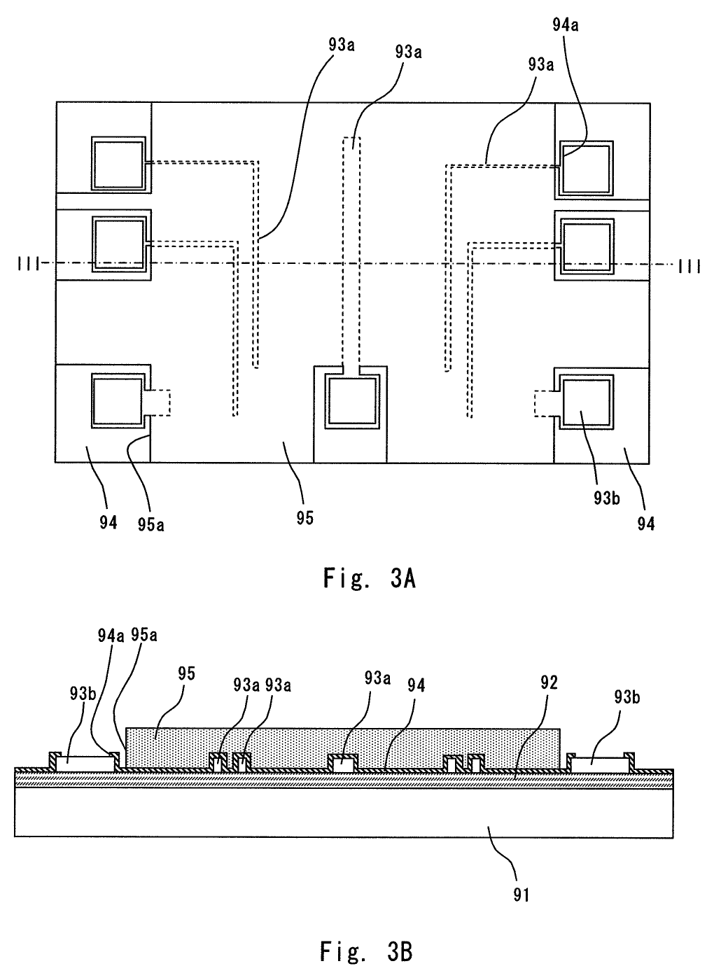

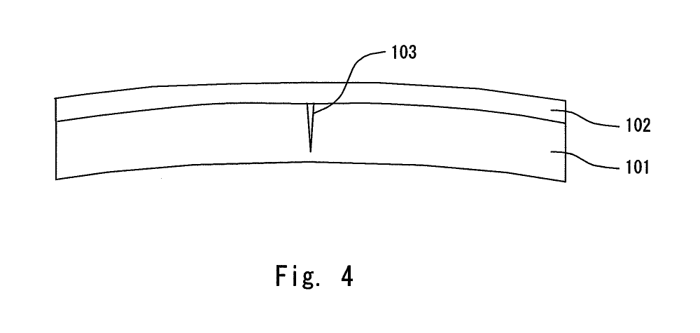

The specific embodiment to which the present invention is applied will now be described in detail with reference to the drawings. FIG. 1A shows a plan view of a semiconductor device according to the embodiment of the present invention. FIG. 1B shows a cross sectional view of the semiconductor device taken along the line I-I of FIG. 1A.

As shown in FIGS. 1A and 1B, an interlayer insulating film 12 is formed on a semiconductor substrate 11 composed of a compound semiconductor such as GaAs or InP, for example. In the present embodiment, a GaAs substrate is employed as the semiconductor substrate 11. Then metal wirings 13a made of Au and electrode pads 13b are formed on the interlayer insulating film 12. The electrode pad 13b is connected to the metal wiring 13a. Each of the metal wirings 13a is formed to have a minimum width of approximately 4 μm and a thickness of approximately 1 to 4 μm. The minimum intervals between the metal wirings 13a (distance between wirings) are approximately 4 μm. A protective insulating film 14 is formed on the interlayer insulating film 12, the metal wirings 13a, and the electrode pads 13b as a passivation film so as to have a film thickness of about 1 μm or less. This protective insulating film 14 is one of a silicon nitride film, a silicon oxide film, and a silicon oxynitride film, for example. The protective insulating film 14 on the electrode pads 13b is removed so that the electrode pads 13b are exposed. That is, the protective insulating film 14 has an pad opening 14a on the electrode pad 13b. Note that a power supply voltage or the like is supplied to the electrode pad 13b through a wire or the like (not shown) connected to the pad opening 14a.

In the present embodiment, a resin film 15 is formed within a region having one side shorter than a predetermined length on the protective insulating film 14. The resin film 15 is formed to cover all the regions having intervals between the metal wirings 13a equal to or less than a predetermined interval. The resin film 15 is formed to cover the metal wirings 13a whose intervals are equal to or less than the predetermined interval for about 1 μm in a height direction and about 1 μm in a horizontal direction. Therefore, the resin film 15 includes a resin film forming region where the resin film 15 is formed in the region having intervals of the metal wirings 13a equal to or less than the predetermined interval. The resin film 15 also includes a resin film non-forming region where the resin film 15 is not formed continuously from one end to the other end of the semiconductor substrate 11. For example, in the present embodiment, the region having one side shorter than the predetermined length, which is the region where the resin film 15 is formed, is regarded as the region having intervals between the metal wirings 13a equal to or less than the predetermined interval. In summary, the resin film 15 is formed only in the region having intervals of the metal wirings 13a equal to or less than the predetermined interval. Thus, it is possible to reduce the stress when the resin film 15 is compressed or stretched, whereby the chip crack of the semiconductor device can be prevented. Especially, in the semiconductor device having the semiconductor substrate 11 composed of the compound semiconductor such as GaAs, the stress of the resin film 15 needs to be considered since the compound semiconductor is fragile. Accordingly, the stress of the resin film 15 can be reduced and the occurrence of the chip crack can be prevented by forming the resin film 15 to cover only the region in which the intervals of the metal wirings 13a are equal to or less than the predetermined interval. Further, it is possible to prevent cracking and the like of the protective insulating film 14 formed on the metal wirings 13a to prevent the occurrence of the migration between the metal wirings 13a.

The resin film 15 is preferably formed within a region having one side shorter than 1000 μm. If the resin film 15 is formed in the region having one side equal to or larger than 1000 μm, it is highly likely that the chip crack occurs due to the stress of the resin film 15. This is the reason why the resin film 15 is preferably formed within the region having one side shorter than 1000 μm. Further, the resin film 15 is preferably formed to cover the metal wirings 13a having predetermined intervals of approximately 50 μm or less. The resin film 15 is preferably formed over the metal wiring 13a when a potential difference of the metal wirings 13a having the intervals equal to or less than the predetermined interval is equal to or larger than 2 V. This is because when the intervals of the metal wirings are equal to or less than the predetermined interval and the metal wirings 13a have the predetermined potential difference, this potential difference may cause the metal to move between wirings, which causes migration. Especially, when the distance between wirings is approximately 50 μm or less and the wirings have the potential difference of 2 V or more, it is highly likely that the migration is caused. Accordingly, the occurrence of the migration can be prevented by forming each resin film 15 over the wirings 13a having intervals of about 50 μm or less and having the potential difference of 2 V or more to prevent the cracking or the like of the protective insulating film 14 formed on the metal wirings 13a. As described above, the resin film 15 includes the resin film non-forming region where the resin film 15 is not formed, and each resin film 15 formed in the resin film forming region is independently formed over the metal wirings 13a whose intervals are equal to or less than the predetermined interval. In summary, each resin film forming region is separately formed with each other. Each resin film 15 is preferably formed along with the metal wirings 13a. The reason thereof will now be described. As stated above, when the resin film 15 is formed over a wide range, the chip crack may occur due to the stress of the resin film 15. Therefore, it is preferable to minimize the resin film forming region where the resin film 15 is formed. Therefore, each resin film 15 disposed in the resin film forming region is preferably formed along with the metal wirings 13a. In the present embodiment, although the resin film forming region where the resin film 15 is formed is limited to the region where the intervals of the metal wirings 13a are equal to or less than the predetermined interval, the resin film forming region covering at least all the regions where the intervals of the metal wirings 13a are equal to or less than the predetermined interval is formed. In this case, the structure of the rein film forming region can be varied as appropriate so long as there is provided the resin film non-forming region continuously from one end to the other end of the substrate. Note that the material of the resin film 15 may be polyimide of PW-N6 series manufactured by Toray Industries, Inc, or may be polybenzo oxazole of CRC8800 series manufactured by Sumitomo Bakelite Co., Ltd, for example.

In the present embodiment, the resin film 15 is formed within the region having one side shorter than the predetermined length. The resin film 15 is formed to cover all the regions in which the intervals of the metal wirings 13a are equal to or less than the predetermined interval. For example, in the present embodiment, the resin film 15 is formed only in the region in which the metal wirings 13a are formed with the intervals equal to or less than the predetermined interval, whereby the stress when the resin film 15 is compressed or stretched can be reduced and the chip crack of the semiconductor device can be prevented. Especially, in the semiconductor device having the semiconductor substrate 11 composed of the compound semiconductor such as GaAs or InP, the stress due to the resin film 15 formed in the semiconductor device needs to be considered since the compound semiconductor is fragile. Accordingly, in the semiconductor device including the semiconductor substrate 11 made of the compound semiconductor such as GaAs or InP, the occurrence of the chip crack can be prevented by forming the resin film 15 in the region in which the intervals of the metal wirings 13a are equal to or less than the predetermined interval in the present embodiment. Further, by forming each resin film 15 over the metal wirings 13a disposed with the intervals equal to or less than the predetermined interval, the cracking or the like of the protective insulating film 14 formed over the metal wirings 13a can be prevented, whereby occurrence of the migration between the metal wirings 13a can be prevented.

It is apparent that the present invention is not limited to the above embodiment but may be modified and changed without departing from the scope and spirit of the invention.

What is claimed is:

1. A semiconductor device, comprising:
a semiconductor substrate;
an interlayer insulating film formed over the semiconductor substrate;
a metal wiring formed over the interlayer insulating film;
a protective insulating film formed on the metal wiring; and
a resin film formed within a region having one side shorter than a predetermined length on the protective insulating film, wherein
the resin film covers all regions having an interval of the metal wirings equal to or less than a predetermined interval.

2. The semiconductor device according to claim 1, wherein the semiconductor substrate is made of a compound semiconductor.

3. The semiconductor device according to claim 2, wherein the compound semiconductor is GaAs or InP.

4. The semiconductor device according to claim 1, wherein the protective insulating film is one of a silicon nitride film, a silicon oxide film, and a silicon oxynitride film.

5. The semiconductor device according to claim 1, wherein the predetermined length is 1000 μm.

6. The semiconductor device according to claim 1, wherein the predetermined interval is 50 μm.

7. A semiconductor device, comprising:
a semiconductor substrate;
an interlayer insulating film formed over the semiconductor substrate;
a metal wiring formed over the interlayer insulating film;
a protective insulating film formed on the metal wiring; and
a resin film formed within a region having one side shorter than a predetermined length on the protective insulating film, wherein
the resin film covers all regions having an applied potential difference of the metal wirings equal to or more than a predetermined potential difference and an interval of the metal wirings equal to or less than a predetermined interval.

8. The semiconductor device according to claim 7, wherein the predetermined potential difference is equal to or more than 2 V.

9. The semiconductor device according to claim 7, wherein the semiconductor substrate is made of a compound semiconductor.

10. The semiconductor device according to claim 9, wherein the compound semiconductor is GaAs or InP.

11. The semiconductor device according to claim 7, wherein the protective insulating film is one of a silicon nitride film, a silicon oxide film, and a silicon oxynitride film.

12. The semiconductor device according to claim 7, wherein the predetermined length is 1000 μm.

13. The semiconductor device according to claim 7, wherein the predetermined interval is 50 μm.
